(19) United States
(12) Patent Application Publication
(10) Pub. No.: US 2011/0031975 A1
(43) Pub. Date: Feb. 10, 2011

(54) Battery-Driven Power Tool and Battery Pack Therefor

(75) Inventors: Yoshikazu Kawano, Hitachinaka-shi (JP); Nobuhiro Takano, Hitachinaka-shi (JP); Eiji Nakayama, Hitachinaka-shi (JP); Kenro Ishimaru, Hitachinaka-shi (JP); Haruhisa Fujisawa, Hitachinaka-shi (JP); Keita Saitou, Hitachinaka-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi Koki Co., Ltd., Minato-ku (JP)

(21) Appl. No.: 12/852,385

(22) Filed: Aug. 6, 2010

(30) Foreign Application Priority Data
Aug. 7, 2009 (JP) 2009-184437

(51) Int. Cl. G01N 27/416; G05B 15/00; G05B 15/02; G08B 21/00; G01R 31/04

(52) U.S. Cl. 324/433; 324/426; 700/275; 700/75; 340/636.1; 324/538

(57) ABSTRACT

A battery pack includes a chargeable battery, a battery voltage detecting section, and a determining section. The battery voltage detecting section is configured to detect a battery voltage output from the rechargeable battery. The determining section is configured to determine a voltage level status of the rechargeable battery based on the battery voltage detected by the battery voltage detecting section. The determining section is free from determining the voltage level status when a rate of change in the battery voltage is equal to or greater than a predetermined criteria. Such a battery pack is used for a power tool.

### CROSS REFERENCE TO RELATED APPLICATION

This application claims priority from Japanese Patent Application No. 2009-184437 filed Aug. 7, 2009. The entire content of the priority application is incorporated herein by reference.

### BACKGROUND

The present invention relates to a battery-driven power tool and a battery pack for use therein.

There has been known a battery-driven power tool having a residual battery capacity indicating capability. The residual battery capacity is indicated by an LED array and thus the user can readily recognize how long the power tool can be used before recharging the battery.

Japanese Patent Application Publication No. 2001-116812 discloses detecting discharge current flowing out from the battery pack when the latter is connected to and used in the power tool and also detecting charge current flowing in the battery pack when charging the same. The amount of electricity charged in or discharged from the battery pack is computed to obtain residual battery capacity. In this technology, measurements of the charge current and the discharge current are performed at all times whenever the battery is recharged and the power tool is driven.

### SUMMARY

The above-described prior art requires a resistor for measuring the current flowing in a charge/discharge current path, so that electric power is dissipated in the resistor. Further, a charge/discharge current detection circuit must be kept active at all times, resulting in dissipation of the battery power.

In view of the foregoing, the present invention has been made to solve the problems accompanying in the prior art residual battery capacity measurement, and accordingly it is an object of the invention to provide a battery-driven power tool and a battery pack for use therein, wherein the residual battery capacity or the battery voltage level status is accurately indicated while saving electric power.

To achieve the above and other objects, there is provided according to the first aspect of the invention a battery pack including a rechargeable battery, a battery voltage detecting section, and a determining section. The battery voltage detecting section is configured to detect a battery voltage output from the rechargeable battery. The determining section is configured to determine a voltage level status of the rechargeable battery based on the battery voltage detected by the battery voltage detecting section. The determining section is free from determining the voltage level status when a rate of change in the battery voltage is equal to or greater than a predetermined criteria.

It is preferable to provide a display section to the battery pack defined above such that the display section indicates the voltage level status of the rechargeable battery determined by the determining section and is selectively operable in a first mode and a second mode different from the first mode, wherein the display section operates in the first mode when the rate of change in the battery voltage is smaller than the predetermined criteria whereas the display section operates in the second mode when the rate of change in the battery voltage has become equal to or greater than the predetermined criteria.

It is further preferable that such display section includes a predetermined number of display elements and is configured such that one or more of selected display elements are lit corresponding to the voltage level status of the rechargeable battery determined by the determining section.

According to the second aspect of the invention, there is provided a battery pack including a rechargeable battery, a connection port, a battery voltage detecting section, a connection port selectively connectable to a power tool body and a battery charger; a display section, and a control section. The battery voltage detecting section is configured to detect a battery voltage output from the rechargeable battery. The control section is configured to determine a voltage level status of the rechargeable battery based on the battery voltage detected by the battery voltage detecting section, control the display section to indicate the voltage level status of the rechargeable battery, and further determine whether connected is the power tool body or the battery charger. The control section is free from determining the voltage level status when the control section determines that the power tool body is connected to the connection port and being driven.

In the battery pack according to the second aspect of the invention, it is preferable that the control section determine that the power tool body is connected to the connection port and being driven when a rate of change in the battery voltage is equal to or greater than a predetermined criteria.

Similar to the first aspect of the invention, it is preferable that the battery pack according to the second aspect of the invention is configured such that the control section controls the display section to be selectively operable in a first mode and a second mode different from the first mode. The display section operates in the first mode when the control section determines that the battery charger is connected to the connection port, and in the second mode when the control section determines that the power tool body is connected to the connection port and being driven.

Such a display section may include a predetermined number of display elements, and one or more of selected display elements are lit corresponding to the voltage level status of the rechargeable battery determined by the control section.

According to a third aspect of the invention, there is provided a battery pack including a rechargeable battery, a connection port, a battery voltage detecting section, a display section, and a control section. The connection port is selectively connectable to a power tool body driven by the rechargeable battery. The battery voltage detecting section is configured to detect an actual battery voltage output from the rechargeable battery at a time when the power tool body is being driven. Detection of the battery voltage is performed at every predetermined interval. The control section is configured to compute, based on two actual battery voltages successively detected by the battery voltage detecting section, a potential battery voltage unaffected by a battery voltage drop temporarily occurring during driving of the power tool body, and control the display section to indicate a voltage level status of the rechargeable battery based on the computed potential battery voltage.

In the battery pack according to the third aspect of the invention, preferably, computation of the potential battery voltage is performed in accordance with an equation:

Va=V1−{(V1−V2)×α}

where V1 represents an actual battery voltage detected by the battery voltage detecting section at a first timing, V2 represents an actual battery voltage detected by the battery voltage detecting section at a second timing subsequent to the first timing, Va represents a potential battery voltage, and a represents a correction factor.

In accordance with another aspect of the invention, there is provided a power tool to which any one of the battery tools according to the first to third aspects of the invention is applied

### BRIEF DESCRIPTION OF THE DRAWINGS

The particular features and advantages of the invention as well as other objects will become apparent from the following description taken in connection with the accompanying drawings, in which:

FIG. 1 is a circuit diagram showing a battery pack and a power tool body in accordance with a first embodiment of the invention;

FIG. 2 is a circuit diagram showing a battery pack and a battery charger in accordance with the first embodiment of the invention;

FIG. 3 is a flowchart illustrating a battery voltage level status displaying process implemented by the battery pack shown in FIG. 1; and

FIG. 4 is a timing chart in accordance with a second embodiment of the invention in which illustrated are actual battery voltages at the time of operating a trigger switch of a power tool and potential battery voltages unaffected by a voltage drop caused by the use of the power tool.

### DETAILED DESCRIPTION

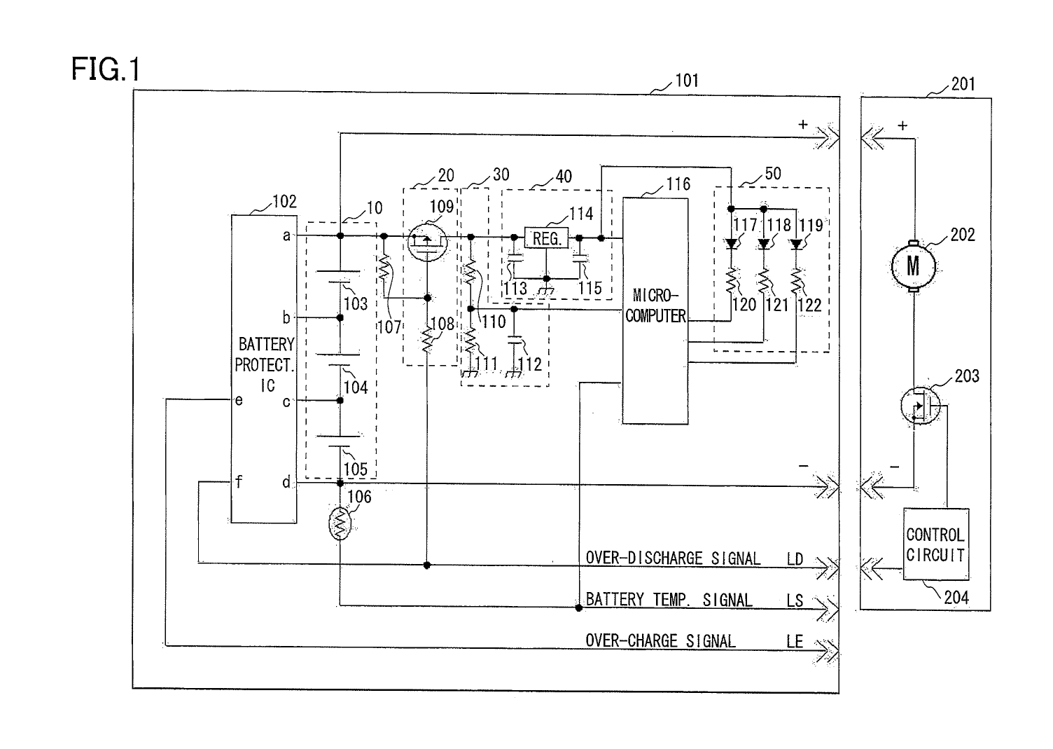

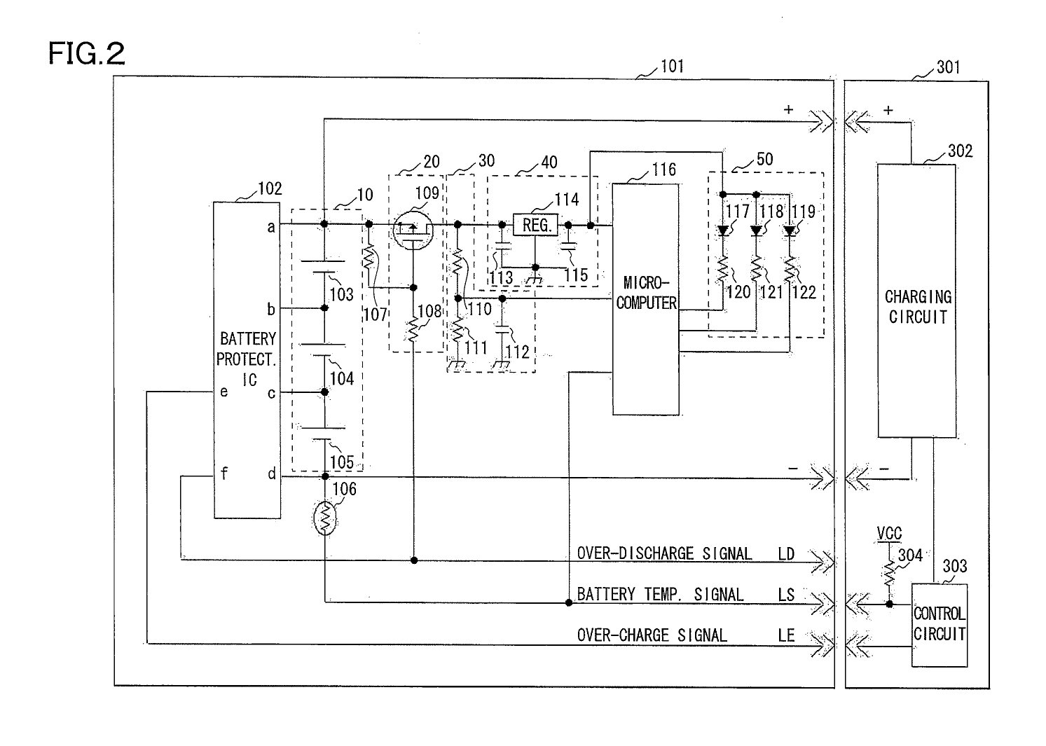

A first embodiment of the invention will be described with reference to FIGS. 1 to 3. FIG. 1 shows a power tool body 201 and a battery pack 101 for use therein. FIG. 2 shows a battery charger 301 for charging the battery pack 101. In the following description, the term “power tool” will be used to refer to such a tool that is operable with a battery pack connected thereto. The term “power tool body” will be used to refer to a body of the power tool to which the battery pack is not connected.

In FIG. 1, the battery pack 101 includes a rechargeable (secondary) battery 10 consisting of three lithium-ion battery cells 103, 104, 105 connected in series. The positive polarity of the battery 10 is connected to the positive terminal (+) of a connection port for electrical connection to the power tool body 201, and the negative polarity of the battery 10 to a negative terminal (−) of the connection port. The power tool body 201 has a connection port for connection of the battery pack 101. A battery charger 301 (see FIG. 2) also has a connection port for connection of the battery pack 101. As will be described later, the connection port of the battery pack 101 has not only the positive (+) and negative (−) terminals but also an over-discharge signal output terminal, a battery temperature signal output terminal and an over-charge signal output terminal.

The battery pack 101 further includes a battery protection IC 102 having a function to monitor the voltage across each cell 103, 104, 105 of the battery 10 and also the total voltage across the battery 10. To this effect, the battery cell 103 is connected between terminals “a” and “b” of he battery protection IC 102, the battery cell 104 between terminals “b” and c”, and the battery cell 105 between terminals “c” and “d”. When the monitored voltages indicate that any cell or battery as a whole is over-discharged, the battery protection IC 102 outputs a high-level over-discharge signal LD from terminal “f”. On the other hand, when the monitored voltages indicate that the battery 10 is in a usable condition, i.e., not in an over-discharged condition, a low-level over-discharge signal is output from terminal “f” of the battery protection IC 102. The high-level over-discharge signal LD is typically produced during driving of the power tool body 201.

When the monitored battery voltages indicate that the battery 10 is overcharged during charging of the battery 10 with the battery charger 301, the battery protection IC 102 outputs an over-charge signal LE from terminal “e”.

A thermistor 106 is connected between the negative terminal of the battery 10 and a battery temperature signal output terminal in the connection port of the battery pack 101. The thermistor 106 is disposed in contact with or in proximity with any of the battery cells to sense the temperature of the battery 10.

When the battery pack 101 is connected to the battery charger 301 as shown in FIG. 2, one terminal of a resistor 304 provided in the battery charger 301 is configured to be connected to the thermistor 106. The other terminal of the resistor 304 is connected to a power supply Vcc. The resistance of the thermistor 106 changes depending upon the temperature of the battery 10. Thus, the voltage developed across the thermistor 106 indicates the temperature of the battery 10 and is applied to both a microcomputer 116 and the battery charger 301 as the battery temperature signal LS.

The battery pack 101 further includes a switching section 20, a battery voltage detecting section 30, a voltage supply section 40, a microcomputer 116 serving as a control section, and a display section 50.

The switching section 20 is configured from resistors 107, 108 and a P-type FET 109. The resistors 107, 108 are connected in series between the source of FET 109 and the over-discharge signal output terminal. The resistor 107 is connected between the source and gate of the FET 109. The source of FET 109 is also connected to the battery 10 and the drain to both the battery voltage detecting section 30 and voltage supply section 40.

The battery voltage detecting section 30 is configured from resistors 110, 111 connected in series between the drain of FET 109 and ground. The battery voltage detecting section 30 is provided for detecting the battery voltage and supplying the detected battery voltage to the microcomputer 116. To this effect, the connection node between the resistors 110 and 111 is connected to the microcomputer to supply the voltage developed across the resistor 111 which indicates the battery voltage.

The voltage supply section 40 is configured from a three-terminal regulator 114 and capacitors 113, 115. The capacitor 113 is connected between the first (input) terminal of the regulator 114 and ground. Another capacitor 115 is connected between the second (output) terminal of the regulator 114 and ground. The third terminal is connected to ground.

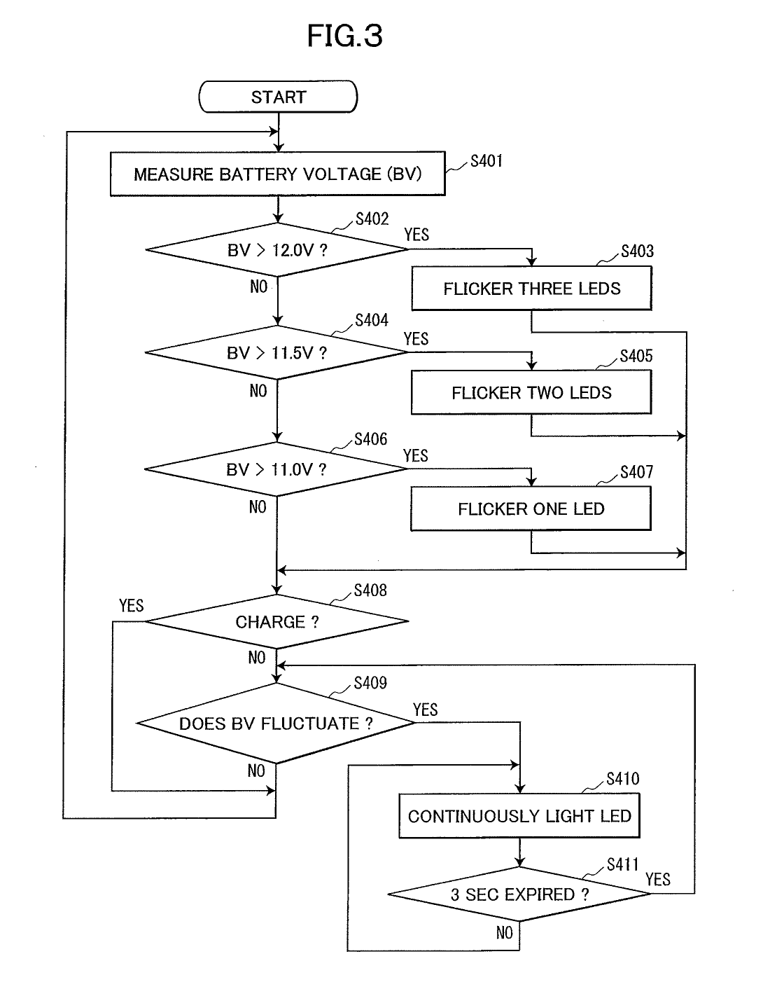

Although not shown in the figures, the microcomputer 116 includes a CPU, a ROM, a RAM, an input port, an A/D converter connected to the input port, and an output port, as is well known in the art. The ROM stores a program for executing a process as shown in FIG. 3.

The display section 50 is configured from three display elements, the first element including a first LED 117 and its associated first resistor 120, the second element including a second LED 118 and its associated second resistor 118, and the third element including a third LED 119 and its associated third resistor 122. Anodes of the first to third LEDs are commonly connected to the output terminal of the voltage supply section 40 and cathodes thereof are connected to separate output ports of the microcomputer 116 through the respective resistors 120, 121, 122. The display section 50 displays a residual capacity of the battery 10 as will be described later in detail.

As described previously, the connection port of the power tool body 201 has the positive (+) and negative (−) terminals configured to be connected to the corresponding terminals of the battery pack 101. The connection port of the power tool body 201 also has an over-discharge signal receiving terminal for receiving the over-discharge signal LD from the battery pack 101.

The power tool body 201 is configured from a motor 202, an N-channel FET 203, and a control circuit 204. The motor 202 is connected between the positive and negative terminals of its own connection port. Connection of the battery pack 101 to the power tool body 201 applies the battery voltage to the motor 202. The FET 203 is interposed between the motor 202 and the negative terminal, and the control circuit 204 is connected to the gate of FET 203 for controlling the same. Specifically, the FET 203 has a drain connected to the motor 202, a source connected to the negative terminal, and a gate connected to the control circuit 204. Although not shown in FIG. 1, the power tool body 201 has a trigger switch to be operated by the user. The trigger switch is connected to the control circuit 204. When the trigger switch is operated, the control circuit 204 outputs a PWM control signal to the gate of the FET 203. Depending upon how much degree the trigger switch is operated by the user, the duty ratio of the PWM control signal is changed so that the rotational speed of the motor 202 is changed in conjunction with the operation degree of the trigger switch. When the control circuit 204 is in receipt of the over-discharge signal LD from the battery pack 101, the control circuit 204 renders the FET 203 off to thereby stop rotations of the motor 202.

As shown in FIG. 2, the battery charger 301 has a connection port for connection to the battery pack 101. The connection port includes positive (+) and negative (−) terminals configured to be connected to the corresponding terminals of the battery pack 101. The connection port of the battery charger 301 further includes a battery temperature signal receiving terminal for receiving the battery temperature signal LS from the battery pack 101, and an over-charge signal receiving terminal for receiving the over-charge signal LE from the battery pack 101.

The battery charger 301 is configured from a charging circuit 302 connected between the positive and negative terminals of its own connection port, and a control circuit 303. The charging circuit 302 supplies a charging current to the battery 10 for recharging the same. The control circuit 303 is connected to the charging circuit 302 for controlling the same during charging. The control circuit 204 controls the charging circuit 302 to halt charging the battery 10 in response to the over-charge signal LE received from the battery protection IC 102 provided in the battery pack 101. The control circuit 303 also monitors the charging status of the battery pack 101 and halt charging when a fully charged condition is detected.

In operation, when the battery 10 is in a usable condition, i.e., not in an over-discharged condition, the low-level over-discharge signal LD is output from terminal “f” of the battery protection IC 102. Due to the low-level over-discharge signal, current flows in the resistors 107 and 108, thereby rendering the FET 109 on. Once the FET 109 is rendered on, the voltage developed across the resistor 111 is applied to the microcomputer 116 and also the battery voltage is applied to the regulator 114 of the voltage supply section 40. The regulator 114 then produces and applies a predetermined fixed voltage to both the microcomputer 116 and the display section 50 to power the same.

When the battery protection IC 102 determines that the voltage across any of the cells 103, 104, 105 or the entire voltage across the battery 10 is lowered, the over-discharge signal LD is changed to a high-level. As a result, the FET 109 is rendered off and neither the microcomputer 116 nor the display section 50 is powered. Not powering these components under the voltage lowered condition of the battery 10 saves power consumption.

When the battery charger 301 is not connected to the battery pack 101, the battery temperature signal LS is at 0 volt. When the battery charger 301 is connected to the battery pack 101, the voltage developed across the thermistor 106 is applied to both the microcomputer 116 and the control circuit 303 of the battery charger 301. The microcomputer 116 can thus determine whether the battery charger 301 is connected or not based on the battery temperature signal LS. The control circuit 303 controls the charging circuit 302 to halt charging when the battery temperature signal LS indicates that the temperature of the battery 10 has reached to a predetermined high level.

Next, a battery voltage level status displaying process will be described with reference to the flowchart shown in FIG. 3.

First, the microcomputer 116 performs measurements of the battery voltage (S401). The battery voltage is divided by the resistors 110 and 111 and the voltage developed across the resistor 111 is applied to the input port of the A/D converter of the microcomputer 116. Based on the measured battery voltage, the microcomputer 116 computes the battery voltage level status, that is, the residual battery capacity, and determines the number of LEDs to be lit (S402 to S407). Incidentally, the measurement or detection of the battery voltage is implemented by the microcomputer 116 in cooperation with the battery voltage detecting section 30.

Specifically, when the battery voltage is higher than 12.0 V (S402: YES), three LEDs 117, 118, 119 are flickered to inform the user that the battery 10 is in a fully or nearly fully charged condition (S403). When the measured battery voltage falls within a range between 11.5 V to 12.0 V (S402:NO, S404: YES), two LEDs 117, 118 are flickered (S405). When the measured battery voltage falls within a range between 11.0 V to 11.5 V (S404: NO, S406: YES), only one LED 117 is flickered (S407). When the measured battery voltage is equal to or lower than 11.0 V (S406: NO), none of the LEDs 117, 118, 119 are flickered to inform the user that the residual battery capacity does not suffice for use. The operating mode of the display section 50 in which the relevant number of LEDs are flickered will be referred to as a first mode.

Next, the microcomputer 116 determines whether the battery charger 301 is connected or not based on the battery temperature signal LS (S408). When the microcomputer 116 determines that the battery charger 301 is not connected to the battery pack 101 (S408: NO), the routine proceeds to S409 where detection of the battery voltage fluctuation is performed. Occurrence of the fluctuation in the battery voltage indicates that the power tool body 201 is connected to the connection port of the battery pack 101 and being driven. The battery voltage is lowered immediately after the motor 202 is driven. Also, the battery voltage fluctuates caused by change in a load current flowing in the motor 202. A PWM signal applied to the FET 203 of the power tool body 201 is also a cause of battery voltage fluctuation. Because the rotational speed of the motor 202 is changed by changing the duty ratio of the PWM signal, the FET 203 is rendered ON and OFF to meet the duty ratio. Whether, the batter voltage is lowered or fluctuated due to the use of the power tool body 201 can be determined based on a rate of change in the battery voltage (or fluctuation rate) during a prescribed period of time is equal to or greater than a predetermined criteria.

When the microcomputer 116 determines that the power tool 301 is being driven (S409: YES) based on the fact that the battery voltage fluctuation has been occurring, the microcomputer 116 continuously light the relevant number of LEDs corresponding to the current battery voltage level status (S410). The operation mode of the display section 50 in which the relevant number of LEDs are continuously lit will be referred to as a second mode. The operation mode of the display section 50 is changed from the first mode to the second mode when the power tool is being driven. When the display section 50 operates in the second mode, measurement of the battery voltage is not performed in the first embodiment. However, the first embodiment may be modified so that measurement of the battery voltage is continuously performed regardless of whether the power tool is being driven or not. In such a modification, the display section 50 still operates in the second mode to continuously light the relevant number of LEDs. It should be noted that the battery voltages measured during driving of the power tool are not used as a basis for determining how many number of LEDs is to be continuously lit. The number of LEDs to be continuously lit is determined based on the battery voltage measured immediately before the power tool is driven.

The relevant number of LEDs is continuously lit for three seconds (S411) to inform the user of the current battery voltage level status. Next, the microcomputer 116 determines whether three (3) seconds have expired (S411). If he determination made in S411 is affirmative (YES), then the routine returns to S409. This means that for three seconds starting from detection of the power tool being driven, the display section 50 is operated in the second mode and the measurement of the battery voltage is not performed in order not to indicate the temporarily lowered battery voltage. It should be noted that the battery voltage is temporarily lowered when the power tool is being driven under a load. The battery voltage measured during driving of the power tool and thus the battery voltage level status determined based on the measured battery voltage is not an accurate information to the user.

Upon expiration of three seconds from the time when determination is made such that the power tool is being driven (S411: YES), further determination is made as to whether or not the power tool is being driven (S409). In 5408, when determination is made such that the battery pack 101 is connected to the battery charger 301, the routine skips to S409 and returns to S401. That is, detection of the battery voltage fluctuate is not performed during charging the battery 10. The value of the predetermined criteria for determining whether the battery voltage is fluctuating is set to be a small value, so that if the process in S409 is executed during charging the battery, the battery voltage level status indicated by the LEDs remains unchanged regardless of the fact that the battery voltage is increasing. It would be more convenient for the user to see the updated battery voltage level during charging the battery.

As described above, according to the first embodiment, the microcomputer 116 serving as a control section determines a battery voltage status, i.e., the remaining battery capacity based on the battery voltage detected by the battery voltage detecting section 30, and the control section does not perform determining the battery voltage status when a rate of change in the battery voltage is equal to or greater than the predetermined criteria. The fact that the rate of change in the battery voltage is equal to or greater than the predetermined criteria indicates that the power tool connected to the connection port of the battery pack 101 is being driven. The battery voltage changes depending upon the load imposed upon the motor 202. The load-dependent battery voltage is not coincidence with the potential or available battery voltage. Accordingly, it is more accurate to indicate the battery voltage status detected immediately before the power tool is driven, rather than indicating the load-dependent battery voltage. Further, power consumption in the battery pack 101 can be reduced by omitting the battery voltage status detection during driving of the power tool.

While it is conceivable to halt the battery voltage status detection when the battery voltage falls below a reference voltage level, degree of accuracy in the battery voltage status to be indicated in the display section would be different between fully charged batteries and nearly empty batteries. The battery voltage lowering degree of the fully charged batteries is much less than that of the nearly empty batteries, so that the battery voltage status detection is performed with respect to the fully charged batteries despite the batteries are used by the power tool body 201 under a load. That is, the load-dependent battery voltage is displayed in the display section 50. On the other hand, according to the first embodiment, the battery voltage status detection is halted when the battery is used under a load. Regardless of whether the battery is fully charged or nearly empty, the battery voltage is lowered if used under a load.

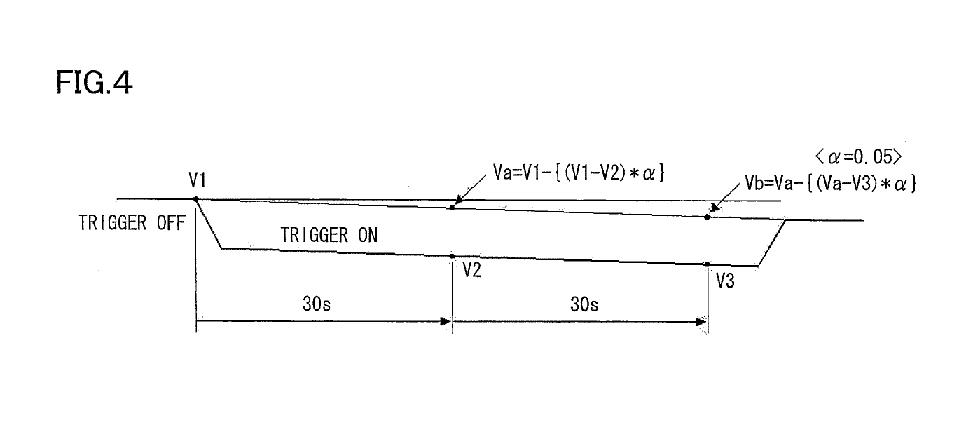

A second embodiment of the invention will next be described with reference to FIG. 4. The circuit structures shown in FIGS. 1 and 2 are also applicable to the second embodiment. In the second embodiment, measurement of the battery voltages with the battery voltage detecting section 30 is performed at all times regardless of whether the power tool is being driven or not. How many number of LEDs is lit in the second mode is determined based on a potential battery voltage. The potential battery voltage is calculated based on actual battery voltages detected by the battery voltage detecting section 30.

FIG. 4 shows a change in actual battery voltage detected by the battery voltage detecting section 30 when the trigger of the power tool body 201 is operated, i.e., when the FET 203 is rendered ON, and also a change in potential battery voltage. The potential battery voltage is such a voltage that is unaffected by a voltage drop temporarily occurring when the trigger switch is operated or constantly occurring during driving of the power tool. Immediately after the trigger switch is operated, the actual battery voltage is abruptly lowered. After the trigger switch is operated, the actual battery voltage is generally gradually lowered. The actual battery voltage tends to fluctuate when the power tool is driven under a load. The battery voltage can be recovered when the trigger switch is released, i.e., when the FET 203 is rendered OFF. The potential voltage of the battery 10 is computed by the microcomputer 116 based on two actual battery voltages successively detected by the battery voltage detecting section 30.

Specifically, in FIG. 4, V1 represents an actual battery voltage detected by the battery voltage detecting section 30 at a first time instant when the trigger switch is operated or immediately before the trigger switch is operated. The actual battery voltage detection is performed at every predetermined interval, 30 seconds in this embodiment. V2 represents an actual battery voltage detected at the second time instant after expiration of 30 seconds from the first time instant. V3 represents an actual battery voltage at a third time instant after expiration of 30 seconds from the second time instant. Va represents a potential battery voltage at the second time instant, and Vb at the third time instant. It can be appreciated that the trigger switch is continuously operated for more than 60 seconds in the example shown in FIG. 4. A rate of change in the actual battery voltage from V1 to V2 is greater than a predetermined criteria described in the first embodiment. Therefore, if the battery voltage change status as shown in FIG. 4 is applied to the first embodiment, determination made in 5409 in the flowchart of FIG. 3 will be affirmative (YES), so that the battery voltage detection is not performed and the display unit 50 displays the battery voltage level status determined immediately before the actual battery voltage is found to be fluctuating.

In the second embodiment, the potential battery voltage Va corresponding to the actual battery voltage V2 is computed by the microcomputer 116 in accordance with the following equation.

Va=V1−{(V1−V2)×α}

α represents a correction factor which is set to 0.05 in the second embodiment. The correction factor a is determined based on experiments. Accordingly, the correction factor a may not necessarily be 0.05 but may be a different value.

Similarly, the potential battery voltage Vb corresponding to the actual battery voltage V3 can also be computed using the previously computed result Va in accordance with the following equation.

Vb=Va−{(Va−V3)×alpa}

In the second embodiment, the display section 50 displays the voltage level status based on the potential battery voltages thus computed, not relying upon the actual battery voltage detected by the battery voltage detecting section 30. As such, detection of the battery voltage level status in accordance with the second embodiment can be more accurately implemented. Display of the computed or predicted battery voltage level status is useful for the user to recognize how long the power tool can be used.

Although the present invention has been described with respect to specific embodiments, it will be appreciated by one skilled in the art that a variety of changes may be made without departing from the scope of the invention.

For example, although in the first embodiment, the detection of the battery voltage is halted when the batter voltage is found to be fluctuating and only the display mode of the display section 50 is changed, the detection f the battery voltage may not be halted but be continued and only the display mode may be changed.

The battery pack 101 shown in FIGS. 1 and 2 includes the battery 10 consisting of three battery cells connected in series. The number of battery cells to be included in the battery pack 101 can be changed. If the number of battery cells is increased to increase the battery voltage, it is preferable that the number of LEDs in the display section 50 be also increased so as to indicate the battery voltage level status more precisely.

What is claimed is:

1. A battery pack comprising:
a rechargeable battery;
a battery voltage detecting section configured to detect a battery voltage output from the rechargeable battery; and
a determining section configured to determine a voltage level status of the rechargeable battery based on the battery voltage detected by the battery voltage detecting section, wherein the determining section is free from determining the voltage level status when a rate of change in the battery voltage is equal to or greater than a predetermined criteria.

2. The battery pack according to claim 1, further comprising a display section configured to indicate the voltage level status of the rechargeable battery determined by the determining section, the display section being selectively operable in a first mode and a second mode different from the first mode, wherein the display section operates in the first mode when the rate of change in the battery voltage is smaller than the predetermined criteria whereas the display section operates in the second mode when the rate of change in the battery voltage has become equal to or greater than the predetermined criteria.

3. The battery pack according to claim 2, wherein the display section comprises a predetermined number of display elements, one or more of selected display elements being lit corresponding to the voltage level status of the rechargeable battery determined by the determining section.

4. A battery pack comprising:
a rechargeable battery;
a connection port selectively connectable to a power tool body and a battery charger;
a battery voltage detecting section configured to detect a battery voltage output from the rechargeable battery;
a display section;
a control section configured to determine a voltage level status of the rechargeable battery based on the battery voltage detected by the battery voltage detecting section, control the display section to indicate the voltage level status of the rechargeable battery, and further determine whether connected is the power tool body or the battery charger, wherein the control section is free from determining the voltage level status when the control section determines that the power tool body is connected to the connection port and being driven.

5. The battery pack according to claim 4, wherein the control section determines that the power tool body is connected to the connection port and being driven when a rate of change in the battery voltage is equal to or greater than a predetermined criteria.

6. The battery pack according to claim 4, wherein the control section controls the display section to be selectively operable in a first mode and a second mode different from the first mode, wherein the display section operates in the first mode when the control section determines that the battery charger is connected to the connection port, and in the second mode when the control section determines that the power tool body is connected to the connection port and being driven.

7. The battery pack according to claim 4, wherein the display section comprises a predetermined number of display elements, one or more of selected display elements being lit corresponding to the voltage level status of the rechargeable battery determined by the control section.

8. A battery pack comprising:
a rechargeable battery;
a connection port selectively connectable to a power tool body driven by the rechargeable battery;
a battery voltage detecting section configured to detect an actual battery voltage output from the rechargeable battery at a time when the power tool body is being driven, detection of the battery voltage being performed at every predetermined interval;
a display section; and
a control section configured to compute, based on two actual battery voltages successively detected by the battery voltage detecting section, a potential battery voltage unaffected by a battery voltage drop temporarily occurring during driving of the power tool body, and control the display section to indicate a voltage level status of the rechargeable battery based on the computed potential battery voltage.

9. The battery back according to claim 8, wherein the control section performs computation of the potential battery voltage in accordance with an equation:
Va=V1−{(V1−V2)×α}
where V1 represents an actual battery voltage detected by the battery voltage detecting section at a first timing, V2 represents an actual battery voltage detected by the battery voltage detecting section at a second timing subsequent to the first timing, Va represents a potential battery voltage, and a represents a correction factor.

10. A power tool comprising:
a power tool body including a motor;
a rechargeable battery connected to the motor;
a battery voltage detecting section configured to detect a battery voltage output from the rechargeable battery; and
a determining section configured to determine a voltage level status of the rechargeable battery based on the battery voltage detected by the battery voltage detecting section, wherein the determining section is free from determining the voltage level status when a rate of change in the battery voltage is equal to or greater than a predetermined criteria.

11. The power tool according to claim 10, further comprising a display section configured to indicate the voltage level status of the rechargeable battery determined by the determining section, the display section being selectively operable in a first mode and a second mode different from the first mode, wherein the display section operates in the first mode when the rate of change in the battery voltage is smaller than the predetermined criteria whereas the display section operates in the second mode when the rate of change in the battery voltage has become equal to or greater than the predetermined criteria.

12. The power tool according to claim 11, wherein the display section comprises a predetermined number of display elements, a selected number of display elements being lit corresponding to the voltage level status of the rechargeable battery determined by the determining section.

13. A power tool comprising:
a power tool body including a motor;
a rechargeable battery;
a connection port selectively connectable to the power tool body and a battery charger;
a battery voltage detecting section configured to detect a battery voltage output from the rechargeable battery;
a display section;
a control section configured to determine a voltage level status of the rechargeable battery based on the battery voltage detected by the battery voltage detecting section, control the display section to indicate the voltage level status of the rechargeable battery, and further determine whether connected is the power tool or the battery charger, wherein the control section is free from determining the voltage level status when the control section determines that the power tool body is connected to the connection port and being driven.

14. The power tool according to claim 13, wherein the control section determines that the power tool body is connected to the connection port and being driven when a rate of change in the battery voltage is equal to or greater than a predetermined criteria.

15. The power tool according to claim 13, wherein the control section controls the display section to be selectively operable in a first mode and a second mode different from the first mode, wherein the display section operates in the first mode when the control section determines that the battery charger is connected to the connection port, and in the second mode when the control section determines that the power tool body is connected to the connection port and being driven.

16. The power tool according to claim 13, wherein the display section comprises a predetermined number of display elements, one or more of selected display elements being lit corresponding to the voltage level status of the rechargeable battery determined by the control section.

17. A power tool comprising:
a power tool body including a motor;
a rechargeable battery;
a connection port selectively connectable to the power tool body driven by the rechargeable battery;
a battery voltage detecting section configured to detect an actual battery voltage output from the rechargeable battery at a time when the power tool body is being driven, detection of the battery voltage being performed at every predetermined interval;
a display section;
a control section configured to compute, based on two actual battery voltages successively detected by the battery voltage detecting section, a potential battery voltage unaffected by a battery voltage drop temporarily occurring during driving of the power tool body, and control the display section to indicate a voltage level status of the rechargeable battery based on the computed potential battery voltage.

18. The power tool according to claim 17, wherein the control section performs computation of the potential battery voltage in accordance with an equation:
Va=V1−{(V1−V2)×α}
where V1 represents an actual battery voltage detected by the battery voltage detecting section at a first timing, V2 represents an actual battery voltage detected by the battery voltage detecting section at a second timing subsequent to the first timing, Va represents a potential battery voltage, and α represents a correction factor.
